(19) United States
(12) Patent Application Publication
(10) Pub. No.: US 2016/0079265 A1
(43) Pub. Date: Mar. 17, 2016

(54) NONVOLATILE SEMICONDUCTOR MEMORY DEVICE AND METHOD OF MANUFACTURING THE SAME

(71) Applicant: Kabushiki Kaisha Toshiba, Minato-ku (JP)

(72) Inventors: Yoshihiro AKUTSU, Yokkaichi (JP); Hisataka Meguro, Yokkaichi (JP)

(73) Assignee: Kabushiki Kaisha Toshiba, Minato-ku (JP)

(21) Appl. No.: 14/645,874

(22) Filed: Mar. 12, 2015

Related U.S. Application Data
(60) Provisional application No. 62/049,848, filed on Sep. 12, 2014.

(51) Int. Cl. H01L 27/115; H01L 21/768; H01L 21/285; H01L 23/532

(52) U.S. Cl. CPC H01L 27/11582; H01L 27/1157; H01L 27/11524; H01L 27/11556; H01L 23/53209; H01L 21/76877; H01L 21/76841; H01L 21/28518

(57) ABSTRACT

This nonvolatile semiconductor memory device includes a semiconductor substrate and a first semiconductor layer formed on a surface of the semiconductor substrate. A memory cell array is formed by coupling a plurality of memory cells in series, and includes a memory string formed to extend in a first direction vertical to the surface of the semiconductor substrate. A contact extends in a direction vertical to the semiconductor substrate, and has one end coupled to the first semiconductor layer. The contact includes: a second semiconductor layer that is formed in the first semiconductor layer and has a higher impurity concentration than that of the first semiconductor layer; a silicide film that has one end coupled to the second semiconductor layer and extends in the first direction; and a metal film formed on an inner wall of the silicide film.

### CROSS REFERENCE TO RELATED APPLICATIONS

This application is based on and claims the benefit of priority from prior U.S. prior provisional Patent Application No. 62/049,848, filed on Sep. 12, 2014, the entire contents of which are incorporated herein by reference.

### FIELD

Embodiments described herein relate generally to a nonvolatile semiconductor memory device and a method of manufacturing the nonvolatile semiconductor memory device.

### BACKGROUND

Recently, in the field of NAND-type flash memories, attention has been focused on a laminated-type (three-dimensional) NAND-type flash memory as a device that can achieve high integration without being restricted by the limit of resolution of the lithography technology. This type of three-dimensional NAND-type flash memory includes a laminated body and a semiconductor layer. In the laminated body, a plurality of conductive films and interlayer insulating films are alternately laminated. The conductive film functions as word lines and selection gate lines. The semiconductor layer is formed to pass through these laminated films. This semiconductor layer functions as a body of a memory string. Between the semiconductor layer and the conductive film, a memory film that includes an electric charge accumulating film is formed.

In this three-dimensional NAND-type flash memory, the resistance of the contact for coupling a memory cell array and an external circuit tends to increase. Accordingly, it is required to reduce the resistance of this contact without increasing the occupation area.

### BRIEF DESCRIPTION OF THE DRAWINGS

FIG. 1 is a perspective view schematically illustrating an exemplary structure of a nonvolatile semiconductor memory device 100 of a first embodiment;

FIG. 2 is a perspective view illustrating a structure of a part of a memory cell array 11;

FIG. 3 is an equivalent circuit diagram of one NAND cell unit NU;

FIG. 4 is a cross-sectional perspective view of one memory cell MC;

FIG. 5 is a plan view of a part of the memory cell array 11;

FIG. 6 is a cross-sectional view of the memory cell array 11 along the Y direction (a cross-sectional view along the X-X′ direction of FIG. 5);

FIG. 7 is a plan view illustrating an exemplary configuration of a wiring portion 20;

FIG. 8 is a process diagram illustrating a method of manufacturing the nonvolatile semiconductor memory device 100 of the first embodiment;

FIG. 9 is a process diagram illustrating the method of manufacturing the nonvolatile semiconductor memory device 100 of the first embodiment;

FIG. 10 is a process diagram illustrating the method of manufacturing the nonvolatile semiconductor memory device 100 of the first embodiment;

FIG. 11 is a process diagram illustrating the method of manufacturing the nonvolatile semiconductor memory device 100 of the first embodiment;

FIG. 12 is a process diagram illustrating the method of manufacturing the nonvolatile semiconductor memory device 100 of the first embodiment;

FIG. 13 is a process diagram illustrating the method of manufacturing the nonvolatile semiconductor memory device 100 of first embodiment;

FIG. 14 is a cross-sectional view illustrating the configuration of the nonvolatile semiconductor memory device of the first embodiment (a cross-sectional view along the X-X′ direction of FIG. 5);

FIG. 15 is a process diagram illustrating a method of manufacturing the nonvolatile semiconductor memory device 100 of a second embodiment;

FIG. 16 is a process diagram illustrating the method of manufacturing the nonvolatile semiconductor memory device 100 of the second embodiment;

FIG. 17 is a process diagram illustrating the method of manufacturing the nonvolatile semiconductor memory device 100 of the second embodiment; and

FIG. 18 is a process diagram illustrating the method of manufacturing the nonvolatile semiconductor memory device 100 of the second embodiment.

### DETAILED DESCRIPTION

A nonvolatile semiconductor memory device according to the embodiments described as follows includes a semiconductor substrate and a first semiconductor layer formed on a surface of the semiconductor substrate. A memory cell array includes a memory string formed to extend in a first direction vertical to the surface of the semiconductor substrate. The memory cell array is formed by coupling a plurality of memory cells in series. A contact extends in a direction vertical to the semiconductor substrate, and has one end coupled to the first semiconductor layer. The contact includes: a second semiconductor layer that is formed in the first semiconductor layer and has a higher impurity concentration than that of the first semiconductor layer; a silicide film that has one end coupled to the second semiconductor layer and extends in the first direction; and a metal film formed on an inner wall of the silicide film.

The following describes nonvolatile semiconductor memory devices according to embodiments in detail with reference to the accompanying drawings. Here, these embodiments are only examples, and are not described for the purpose of limiting the present invention. For example, in the following nonvolatile semiconductor memory devices, the memory string has the structure that extends in a straight line vertical to the substrate. The present invention is also applicable to a device that has a U shape by folding the memory string in the middle to the opposite side. The respective drawings of the nonvolatile semiconductor memory devices used in the following embodiments are schematically illustrated. The thickness, the width, the ratio, and similar parameter of the layer are different from actual parameters.

The following embodiments relate to a nonvolatile semiconductor memory device in a structure where a plurality of metal-oxide-nitride-oxide-semiconductor (MONOS) type memory cells (transistors) is disposed in a height direction. The MONOS type memory cell includes: a semiconductor film disposed in a columnar shape vertical to the substrate as a channel, and a gate electrode film disposed on the side surface of the semiconductor film via an electric charge accumulating layer. However, this is not also intended to limit the present invention. The present invention is applicable to the electric charge accumulating film of another type, for example, a semiconductor-oxide-nitride-oxide-semiconductor type (SONOS) memory cell or a floating-gate type memory cell.

### First Embodiment

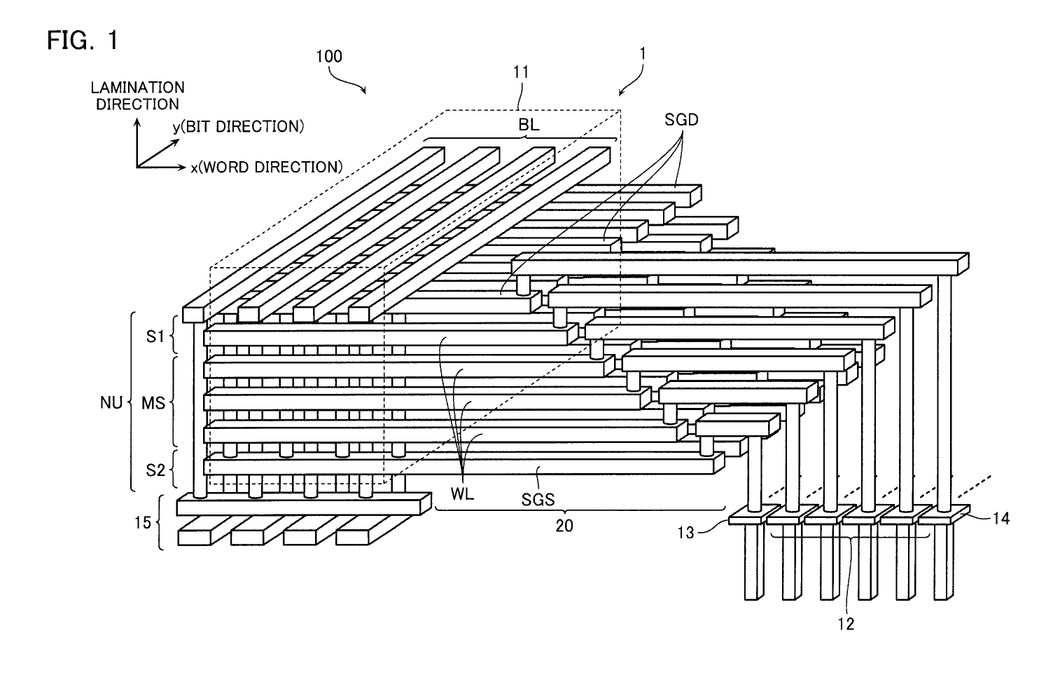

FIG. 1 is a perspective view schematically illustrating an exemplary structure of a nonvolatile semiconductor memory device 100 of a first embodiment. The nonvolatile semiconductor memory device 100 includes a memory cell array 11, word-line driving circuits 12, source-side selection-gate-line driving circuits 13, drain-side selection-gate-line driving circuits 14, a sense amplifier 15, word lines WL, source-side selection gate lines SGS, drain-side selection gate lines SGD, bit lines BL, word-line wiring portions, and similar portion.

The memory cell array 11 includes memory strings MS, drain-side selection transistors S1, and source-side selection transistors S2 on a semiconductor substrate (not illustrated in FIG. 1). The memory string MS is constituted such that a plurality of memory cells MC (memory transistors) are coupled together in series. The respective drain-side selection transistor S1 and source-side selection transistor S2 are coupled to both ends of the memory string MS. Here, the series circuit that includes: the memory string MS, and the drain-side selection transistor S1 and the source-side selection transistor S2 coupled to both ends of the memory string MS are hereinafter referred to as a “NAND cell unit NU.”

As described later, the memory cell MC has the structure where a control gate electrode (word line) is disposed on the side surface of a columnar semiconductor film to be a channel via a memory film including an electric charge accumulating layer. The drain-side selection transistor and the source-side selection transistor each have the structure where a selection gate electrode (selection gate line) is disposed on the side surface of a columnar semiconductor film via a memory film including an electric charge accumulating layer. For simplification of the illustration, FIG. 1 illustrates the case where four memory cells MC are disposed in one memory string MS as the example. Obviously, the number of the memory cells MC in one memory string MS is not limited to this.

The word line WL is coupled in common to the adjacent memory cells along the X direction (the word-line direction) in FIG. 1. The source-side selection gate line SGS is coupled in common to the adjacent source-side selection transistors S2 along the word-line direction. The drain-side selection gate line SGD is coupled in common to the adjacent drain-side selection transistor S1 along the word-line direction. Here, in the following description, the source-side selection gate line SGS and the drain-side selection gate line SGD are collectively referred to simply as “selection gate lines” in some cases. The source-side selection transistor and the drain-side selection transistor are collectively referred to simply as “selection transistors” in some cases. Here, in the memory cells MC in the memory string MS, one or a plurality of the memory cells MC close to the source-side selection gate line SGS and the drain-side selection gate line SGD may be treated as a dummy cell that is not used for data storage. Also in the example described as follows, a description will be given of the example where one dummy cell is disposed at each of both ends of the memory string MS. This, however, should not be construed in a limiting sense. Two or more dummy cells may be disposed or the dummy cell may be omitted.

Furthermore, the bit lines BL are disposed to extend in the Y direction (the bit-line direction) intersecting with the X direction (the word-line direction), and are collocated at a predetermined pitch in the X direction. The bit line BL is coupled to a plurality of the memory strings MS via the drain-side selection transistors Sl. Source lines SL, which are omitted in FIG. 1, are similarly disposed having the longitudinal direction in the Y direction and coupled to the memory strings MS via the source-side selection transistors S2.

The word-line driving circuit 12 is a circuit that controls the voltage to be applied to the word line WL. The source-side selection-gate-line driving circuit 13 is a circuit that controls the voltage to be applied to the source-side selection gate line SGS. The drain-side selection-gate-line driving circuit 14 is a circuit that controls the voltage to be applied to the drain-side selection gate line SGD. The sense amplifier 15 is a circuit for amplifying a signal (voltage) read out from a selected memory cell to the bit line BL.

A wiring portion 20 is a wiring portion for coupling the word lines WL and the selection gate lines SGD and SGS to the contacts. The word lines WL, the selection gate lines SGS and SGD have a structure processed in a staircase pattern such that the respective upper portions can independently be coupled to the contacts.

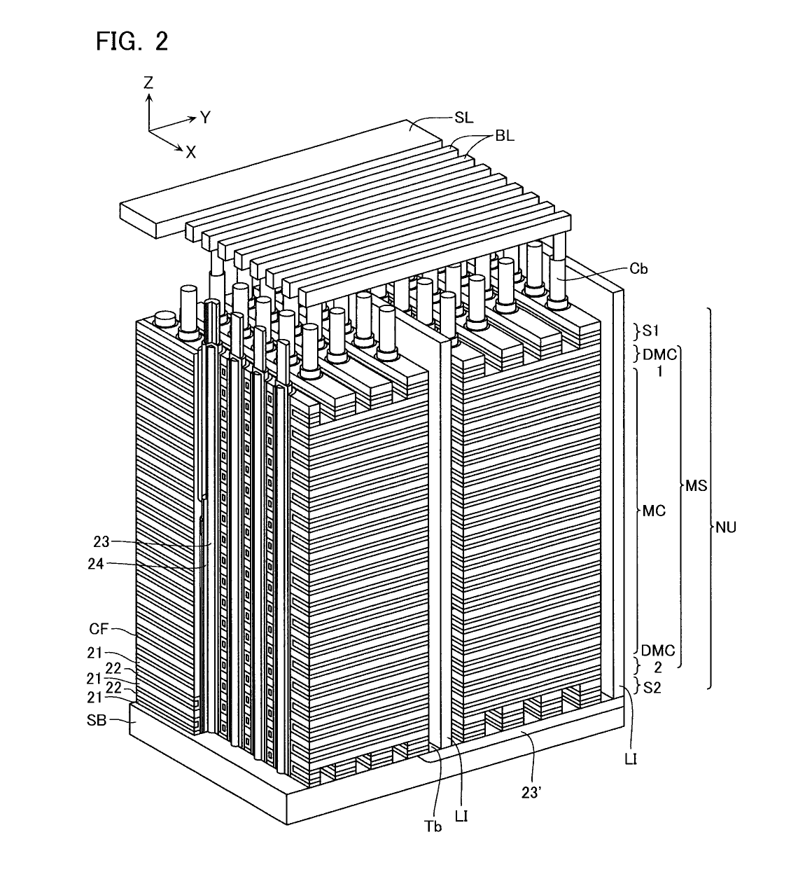

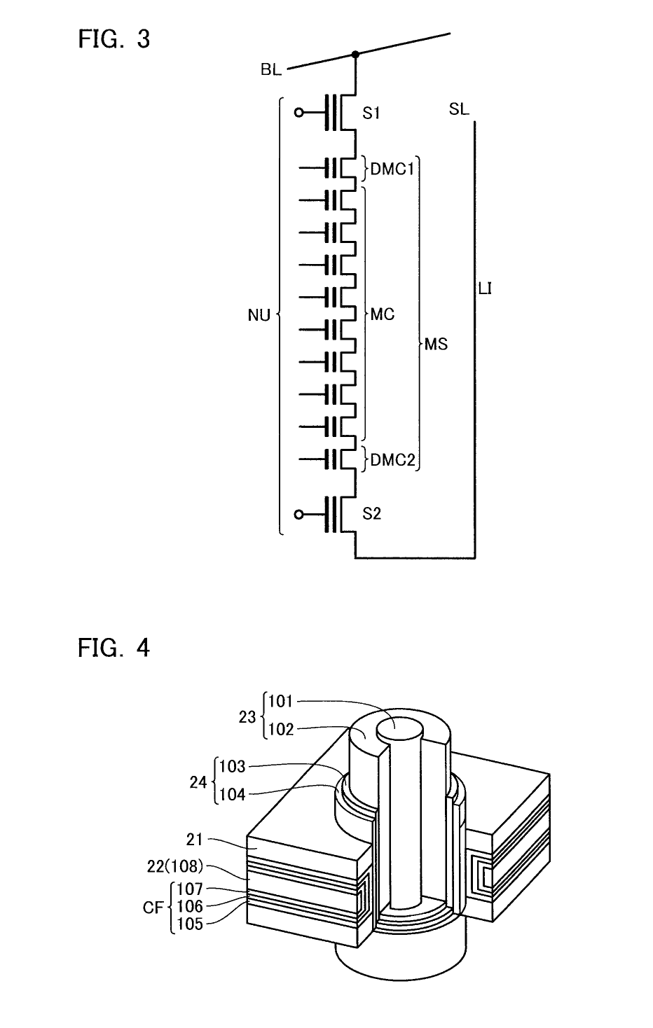

The following describes the detail of the structure of the memory cell array 11 with reference to FIG. 2 to FIG. 4. FIG. 2 is a perspective view illustrating the structure of a part of the memory cell array 11. FIG. 3 is an equivalent circuit diagram of one NAND cell unit NU. FIG. 4 is a cross-sectional perspective view of one memory cell MC or similar part.

As illustrated in FIG. 2, the memory cell array 11 has the structure where interlayer insulating films 21 and conductive films 22 are alternately laminated on a semiconductor substrate SB. These conductive films 22 function as control gates (word lines WL) of the memory cell MC, the source-side selection gate line SGS, and the drain-side selection gate line SGD. The interlayer insulating films 21 are disposed in the up-and-down direction of these conductive films 22 to electrically insulate the conductive films 22 from one another.

The conductive film 22 can be formed of, for example, tungsten (W), tungsten nitride (WN), tungsten silicide (WSix), tantalum (Ta), tantalum nitride (TaN), tantalum silicide (TaSix), palladium silicide (PdSix), erbium silicide (ErSix), yttrium silicide (YSix), platinum silicide (PtSix), hafnium silicide (HfSix), nickel silicide (NiSix), cobalt silicide (CoSix), titanium silicide (TiSix), vanadium silicide (VSix), chrome silicide (CrSix), manganese silicide (MnSix), iron silicide (FeSix), ruthenium (Ru), molybdenum (Mo), titanium (Ti), titanium nitride (TiN), vanadium (V), chrome (Cr), manganese (Mn), iron (Fe), cobalt (Co), nickel (Ni), gold (Au), silver (Ag) or copper (Cu), or can be formed of a compound of these materials. The conductive film 22 may be formed of polysilicon with the addition of impurities.

In the peripheral area of the conductive film 22, a laminated film CF is formed. The laminated film CF includes a block insulating film 105, a block high-dielectric film 106, and a barrier metal 107. This point will be described later.

To pass through this laminated body of the interlayer insulating film 21 and the conductive film 22, semiconductor layers 23 having the longitudinal direction in the lamination direction (Z direction) are disposed at a predetermined pitch in the XY plane. Between: the semiconductor layer 23; and the conductive film 22 and the interlayer insulating film 21, a memory film 24 including an electric charge accumulating layer is formed. As described later, the memory film 24 can be formed by a laminated structure of: an electric charge accumulating film such as a silicon nitride film, and an oxide film such as a silicon oxide film. Depending on the accumulation amount of the electric charge to this electric charge accumulating film, the threshold voltage of the memory cell MC changes. The memory cell MC holds data corresponding to this threshold voltage.

The semiconductor layers 23 function as the channel regions (body) of the memory cell MC, the dummy cells DMC1 and DMC2, and the selection transistors S1 and S2 that are included in the NAND cell unit NU. These semiconductor layers 23 are coupled, on their upper ends, to the bit lines BL via contacts Cb. The bit lines BL having the longitudinal direction in the Y direction are collocated at a predetermined pitch along the X direction.

The lower end of the semiconductor layer 23 is coupled to a semiconductor layer 23′ (first semiconductor layer) formed on the surface of the semiconductor substrate SB. That is, the lower end of the semiconductor layer 23 is coupled to the source line SL via this semiconductor layer 23′ and a contact LI described later. The source lines SL are collocated to have the longitudinal direction in the Y direction, similarly to the bit lines BL.

Here, the laminated body of the interlayer insulating film 21 and the conductive film 22 in the memory cell array 11 are separated by blocks as the smallest unit of data erasure. At the boundary of the separation, a trench Tb is formed. In this trench Tb, an interlayer insulating film (not illustrated in FIG. 1) is implanted. Further, the contact LI described above is formed passing through the interlayer insulating film. In this contact LI, the lower end is coupled to the semiconductor layer 23′ on the surface of the semiconductor substrate SB while the upper end is coupled to the source line SL.

FIG. 3 is an equivalent circuit diagram of one NAND cell unit NU. In this memory cell array 11, the one NAND cell unit NU includes the memory string MS, the drain-side selection transistor S1, and the source-side selection transistor S2. The memory string MS is constituted of a plurality of the memory cells MC and dummy cells DMC1 and DMC2. The drain-side selection transistor S1 is coupled between the upper end of the memory string MS and the bit line BL. The source-side selection transistor S2 is coupled between the lower end of the memory string MS and the source line SL.

FIG. 4 illustrates one example of a specific structure of one of the memory cell MC and the dummy cell DMC. The semiconductor layer 23 includes an oxide-film core 101 and a semiconductor columnar portion 102 that surrounds the peripheral area of the oxide-film core 101. The oxide-film core 101 is formed of, for example, a silicon oxide film (SiO2). The semiconductor columnar portion 102 is formed of, for example, silicon (Si), silicon-germanium (SiGe), silicon carbide (SiC), germanium (Ge), or carbon (C).

In the peripheral area of this semiconductor columnar portion 102, a tunnel insulating film 103 and an electric charge accumulating layer 104 are formed to surround this semiconductor columnar portion 102. The tunnel insulating film 103 is constituted of, for example, a silicon oxide film (SiOx), and functions as a tunnel insulating film of the memory cell MC or the dummy cell DMC. The electric charge accumulating layer 104 is constituted of, for example, a silicon nitride film (SiN), and has a function that traps electrons injected from the semiconductor columnar portion 102 via the tunnel insulating film 103 by a write operation. In this example, the tunnel insulating film 103 and the electric charge accumulating layer 104 are illustrated to be formed on the entire side surface of the semiconductor columnar portion 102. This, however, should not be construed in a limiting sense. The tunnel insulating film 103 and the electric charge accumulating layer 104 can be formed only on the side surface of the word line WL.

On the side surface of the electric charge accumulating layer 104, the above-described interlayer insulating film 21 and a tungsten electrode 108, which functions as the conductive film 22, are alternately laminated. However, in the peripheral area of the tungsten electrode 108, the block insulating film 105, the block high-dielectric film 106, and the barrier metal 107 are formed in this order from the outer side to surround the tungsten electrode 108. The block insulating film 105 can be formed of, for example, a silicon oxide film. In this example, the block insulating film 105 is formed to cover the peripheral area of the tungsten electrode 108. The block insulating film 105 can be formed on the entire side surface of the semiconductor columnar portion 102, similarly to the tunnel insulating film 103 and the electric charge accumulating layer 104.

Here, the materials of the tunnel insulating film 103 and the block insulating film 105 can employ, for example, Al₂O₃, Y₂O₃, La₂O₃, Gd₂O₃, Ce₂O₃, CeO₂, Ta₂O₅, HfO₂, ZrO₂, TiO₂, HfSiO, HfAlO, ZrSiO, ZrAlO, and AlSiO other than the silicon oxide film (SiOx).

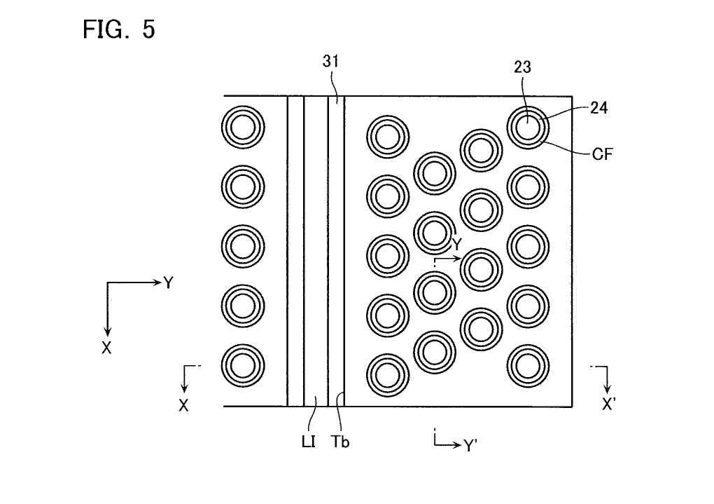

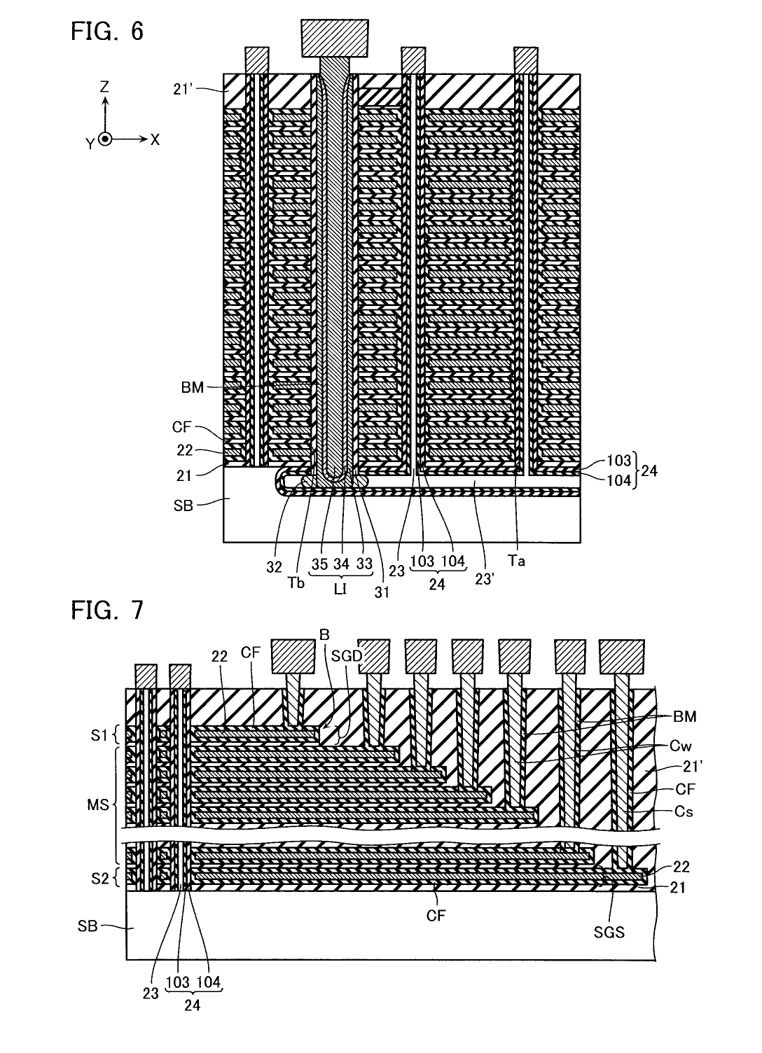

The following describes the further detail of the structures of the memory cell array 11 and the wiring portion 20 with reference to FIG. 5 to FIG. 7. FIG. 5 is a plan view of a part of the memory cell array 11. FIG. 6 is a cross-sectional view of the memory cell array 11 along the Y direction (a cross-sectional view along the X-X′ direction in FIG. 5). FIG. 7 is a plan view of the wiring portion 20.

As illustrated in FIG. 5, the semiconductor layers 23 (the oxide-film core 101 and the semiconductor columnar portion 102) are arrayed in one row in the oblique direction with respect to the X direction (the word-line direction) and the Y direction (the bit-line direction). This increases the array density of the semiconductor layer 23, thus increasing the array density of the memory cell MC. However, this is only one example, and the semiconductor layers 23 can be disposed along the X direction and the Y direction. The contact LI is formed in a stripe shape to have the longitudinal direction in the X direction, and is implanted in the trench Tb via an interlayer insulating film 31.

As illustrated in FIG. 6, multiple trenches Ta are formed to pass through the interlayer insulating films 21 and the conductive films 22, which are laminated on the semiconductor substrate SB. The memory film 24 (the laminated film of the tunnel insulating film 103 and the electric charge accumulating layer 104) is formed along the sidewall in this trench Ta. Further, the semiconductor layer 23 is implanted in the firther inner part of the trehch Ta. The conductive film 22 is formed in contact with the memory film 24. In the peripheral area of the conductive film 22, the above-described laminated film CF (the laminated film formed of the block insulating film 105, the block high-dielectric film 106, and the barrier metal 107) is formed. That is, the conductive film 22 is in contact with the memory film 24 via this laminated film CF.

The above-described contact LI is implanted in the trench Tb, which divides the memory cell array 11 by blocks, via the interlayer insulating film 31. In the contact LI, the lower end is in contact with the semiconductor layer 23′ formed on the surface of the substrate SB while the upper end is coupled to the source line SL via upper-layer wiring. Here, in the example of FIG. 6, the peripheral area of the semiconductor layer 23′ is covered with the memory film 24 similarly to the semiconductor layer 23 constituting the memory string. However, it is obviously possible to employ the configuration where the memory film 24 is formed only in the peripheral area of the semiconductor layer 23.

As illustrated in FIG. 6, the contact L1 is formed of a multi-layer structure that includes a semiconductor layer 32 (second semiconductor layer), a silicide film 33, a barrier metal film 34, and a metal film 35. The semiconductor layer 32 is formed by diffusion of impurities in the semiconductor layer 23′, and has a higher impurity concentration than that of the semiconductor layer 23′. One end of the silicide film 33 is coupled to the semiconductor layer 32. The semiconductor layer 32 with the high impurity concentration is sandwiched between the silicide film 33 and the semiconductor layer 23′. This allows ensuring a low-resistance schottky junction, and facilitates the generation of what is called gate-induced-drain-leakage current (GIDL current) in an erasing operation of the memory.

The silicide film 33 is formed on the sidewall of the trench Tb via the interlayer insulating film 31, and is formed to have the longitudinal direction in the lamination direction. As described later, the silicide film 33 is formed by further depositing a metal film (such as nickel (Ni) and cobalt (Co)) on the silicon film formed on the sidewall of the interlayer insulating film 31 and by silicidizing this silicon film. The silicide film 33 has the film thickness (for example, approximately 20 nm to 30 nm) to the extent that the entire silicon layer can be silicidized by one silicidation process.

The barrier metal film 34 is formed along the inner wall of this silicide film 33. The barrier metal film 34 is formed by, for example, titanium nitride (TiN) or a laminated structure of titanium nitride and titanium. Further, the metal film 35 is formed on the inner wall of the trench Tb, that is, the silicide film 33 along the barrier metal film 34. The metal film 35 is constituted of, for example, metal such as tungsten (W). Thus, the contact LI according to this embodiment is formed of the multi-layer structure that includes the silicide film 33 in contact with the interlayer insulating film 31, the barrier metal film 34, and the metal film 35. The silicon layer is replaced by the silicide film 33. This allows reducing the resistance of the contact LI compared with the case where silicon is used as the material.

In the nonvolatile semiconductor memory device of the first embodiment, the barrier metal film 34 is formed on the silicide film 33. The barrier metal film 34 can employ a film of titanium nitride (TiN) alone. In this case, the production cost can be reduced.

Alternatively, the laminated film of titanium nitride (TiN) and titanium (Ti) can be used as the barrier metal film 34. In this case, titanium (Ti) is further silicidized on the silicide in the silicide film 33 to form titanium silicide, so as to ensure a dual silicide structure. This dual silicide structure reduces an excessive reaction of titanium silicide compared with the case where titanium is deposited on the silicon layer so as to form titanium silicide. Accordingly, a void is less likely to occur in the barrier metal film 34. This allows improving the yield of the contact LI. In the case where the laminated film of titanium nitride (TiN) and titanium (Ti) is used as the barrier metal film 34, the presence of titanium (Ti) allows reducing an increase in resistance of the silicide film 33 due to formation of a natural oxide film on silicide in the silicide film 33.

The following describes the structure of the wiring portion 20 with reference to FIG. 7. As described above, the wiring portion 20 is a wiring portion for coupling the conductive film 22, which functions as the word lines WL or the selection gate lines SGD or SGS, to an external circuit via a contact. The conductive film 22, which functions as the word lines WL and the selection gate lines SGD and SGS, is processed in a staircase pattern in this wiring portion 20 together with the interlayer insulating film 21. Accordingly, each upper portion can be independently coupled to a contact Cw or Cs. The conductive film 22, which functions as the word lines WL, is coupled to the word-line driving circuit 12 illustrated in FIG. 1 by the contact Cw. The conductive film 22, which functions as the selection gate lines SGS and SGD, is coupled by the contact Cs and the conductive film 22, which functions as the word lines WL illustrated in FIG. 1, is coupled by the contact Cw to the source-side selection-gate-line driving circuit 13 or the drain-side selection-gate-line driving circuit 14 illustrated in FIG. 1. The contact Cw or Cs is implanted in the trench formed in an interlayer insulating film 21′ via a barrier metal BM.

### Manufacturing Method

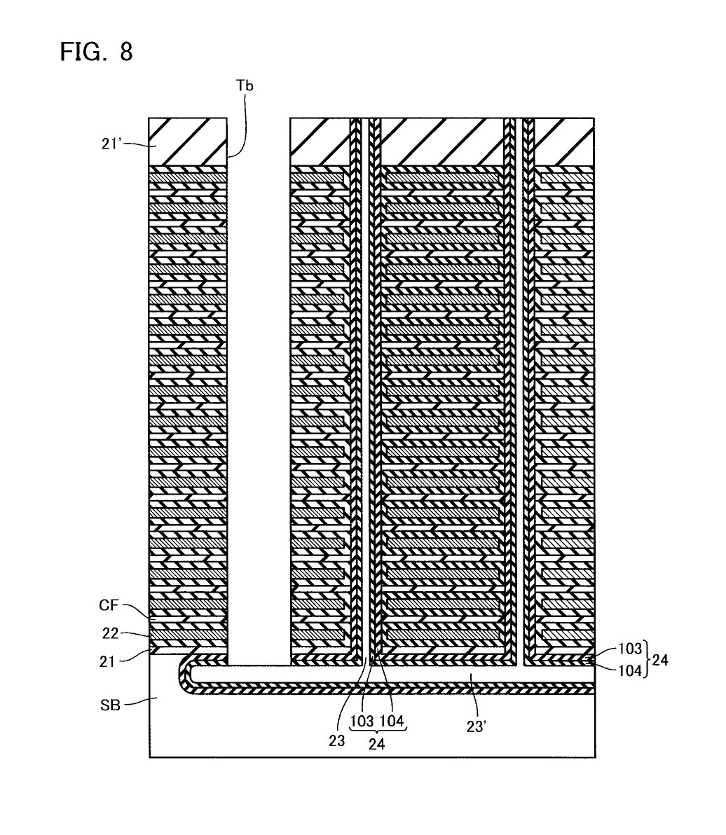

The following describes a method of manufacturing the portion of the contact LI in the nonvolatile semiconductor memory device 100 of the first embodiment with reference to FIG. 8 to FIG. 11. The method of manufacturing the portion of the memory cell array 11 can employ, for example, the method similar to that in Japanese Unexamined Patent Application Publication No. 2011-165972, and therefore will not be further elaborated here.

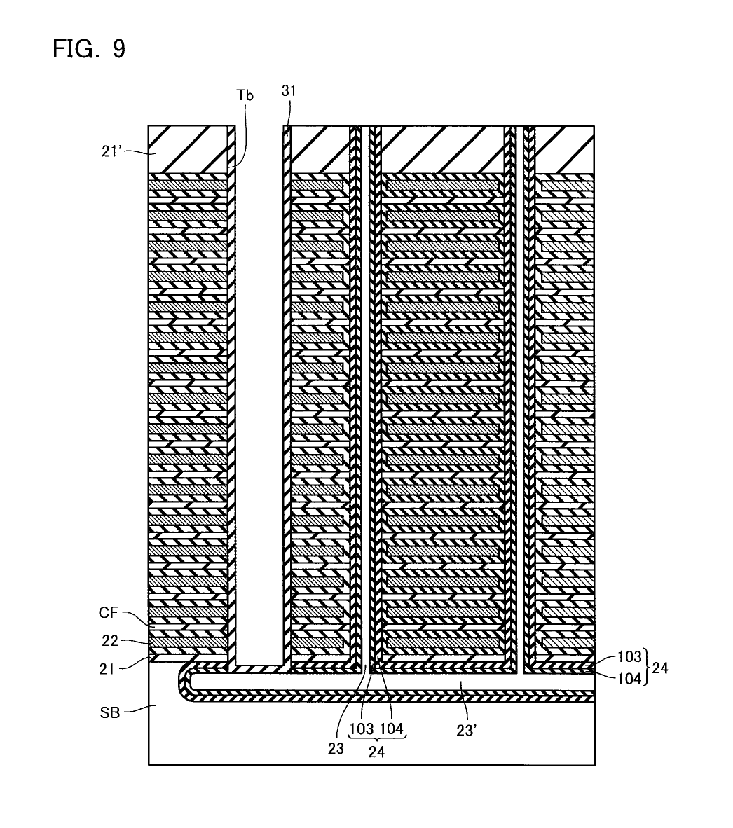

Firstly, as illustrated in FIG. 8, the portion of the NAND cell unit in the memory cell array 11 is formed by the above-described known method, and then the above-described trench Tb is formed. On the side surface of this trench Tb, as illustrated in FIG. 9, the interlayer insulating film 31 is formed using, for example, a CVD method.

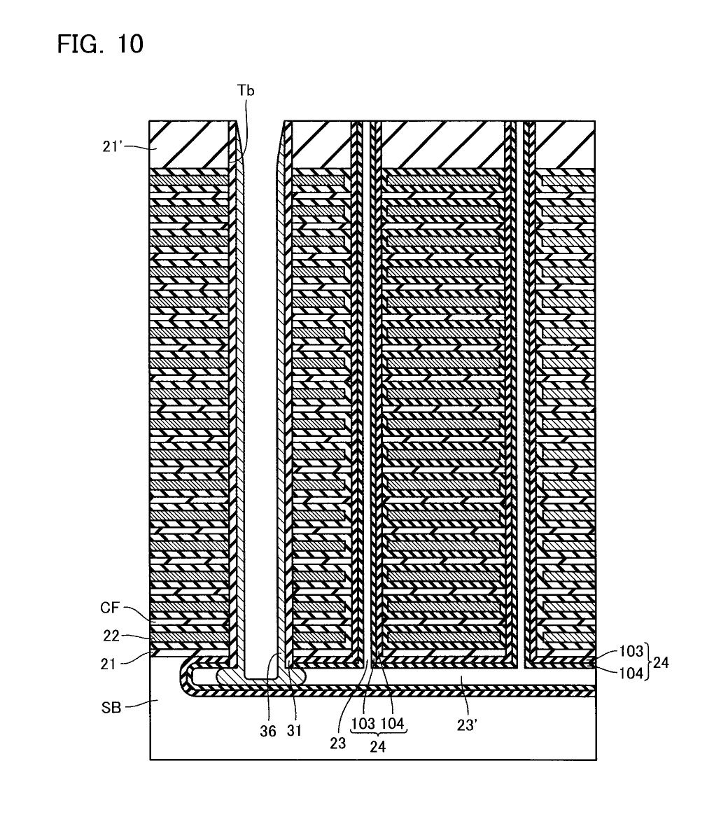

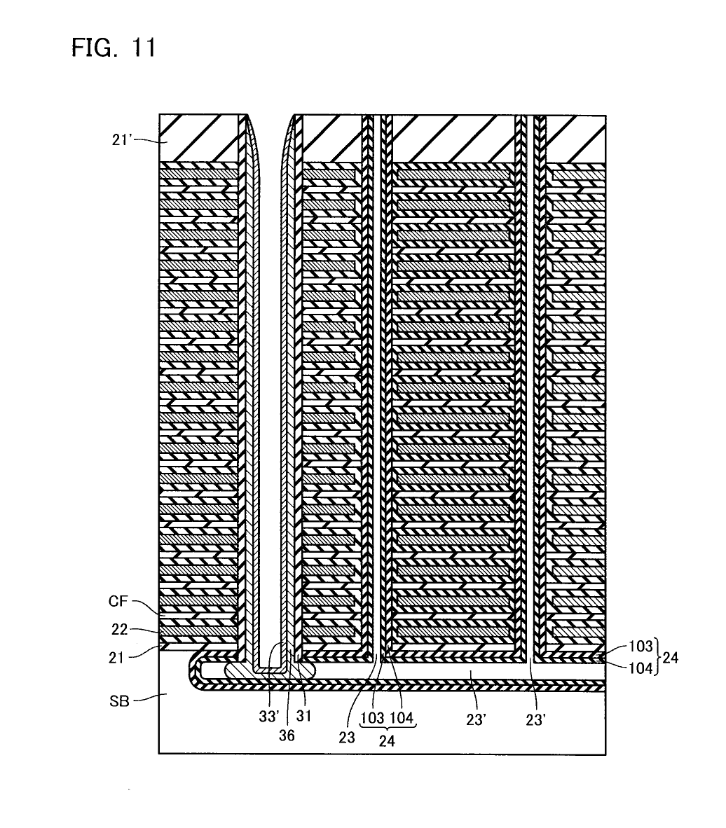

Subsequently, etching is performed to remove the interlayer insulating film 31 in the bottom portion of the trench Tb. Subsequently, as illustrated in FIG. 10, a polysilicon film 36 containing impurities such as boron (B) is deposited on the sidewall of the trench Tb. After the deposition, an annealing treatment is performed at a predetermined temperature. Accordingly, a part of the impurities in the polysilicon film 36 is also diffused to the outer side of the trench Tb in the semiconductor layer 23′.

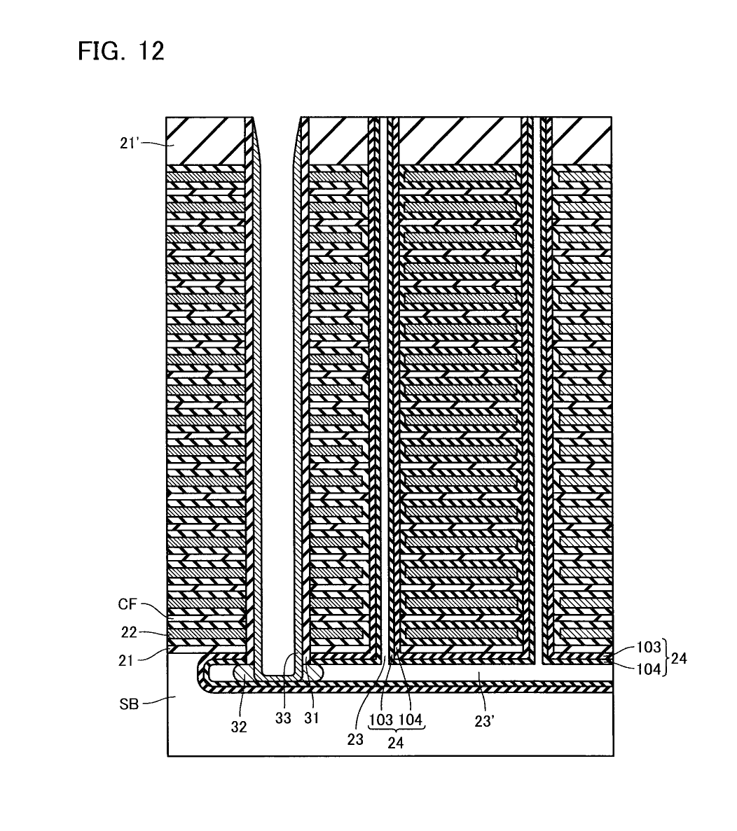

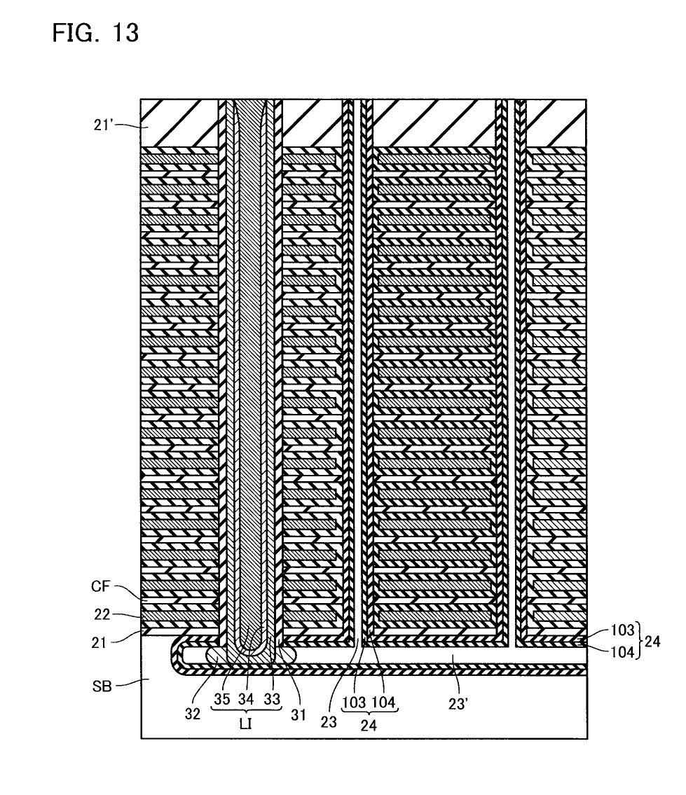

Subsequently, as illustrated in FIG. 11, a metal film 33′ such as nickel (Ni) and cobalt (Co) is deposited on the inner wall of the polysilicon film 36 using, for example, a sputtering method or similar method. Subsequently, the silicidation process is performed to silicidize polysilicon in the polysilicon film 36. With the silicidation, the polysilicon film 36 is changed into the silicide film 33 (see FIG. 12). However, on the outer side of the trench Tb in the semiconductor layer 23′, the polysilicon film 36 is not silicidized and left so as to be formed as the semiconductor layer 32.

Subsequently, as illustrated in FIG. 13, the metal film 33′ left in the silicidation process is removed by wet etching or similar process. Subsequently, the barrier metal film 34 formed of titanium nitride (TiN) and similar material is deposited on the inner wall of the silicide film 33. Further, the metal film 35 formed of tungsten (W) or similar material is deposited on the inner wall of the barrier metal film 34 to fill the trench Tb. With the above-mentioned processes, the contact LI is completed.

### Effects

As described above, in the nonvolatile semiconductor memory device of the first embodiment, the contact LI is formed by the multi-layer structure of the silicide film 33, the barrier metal film 34, and the metal film 35. The silicon film is replaced by the silicide film 33. This allows reducing the resistance of the contact LI, thus reducing the power consumption. The small resistance of the contact LI allows decreasing the dimension of the contact LI in the lateral direction, thus being useful for downsizing the nonvolatile semiconductor memory device.

In this first embodiment, the silicon film in the contact LI is replaced by the silicide film 33 so as to form the barrier metal film 34 on this the silicide film 33. In this case, the barrier metal film 34 can be formed as, for example, a single-layer film of titanium nitride. This allows reducing the production cost compared with the case where the barrier metal film is formed to have the laminated structure of titanium nitride and titanium.

On the other hand, in the case where the barrier metal film 34 employs the laminated film of titanium nitride and titanium, this allows reducing an increase in resistance due to formation of the natural oxide film on the silicide film 33.

### Second Embodiment

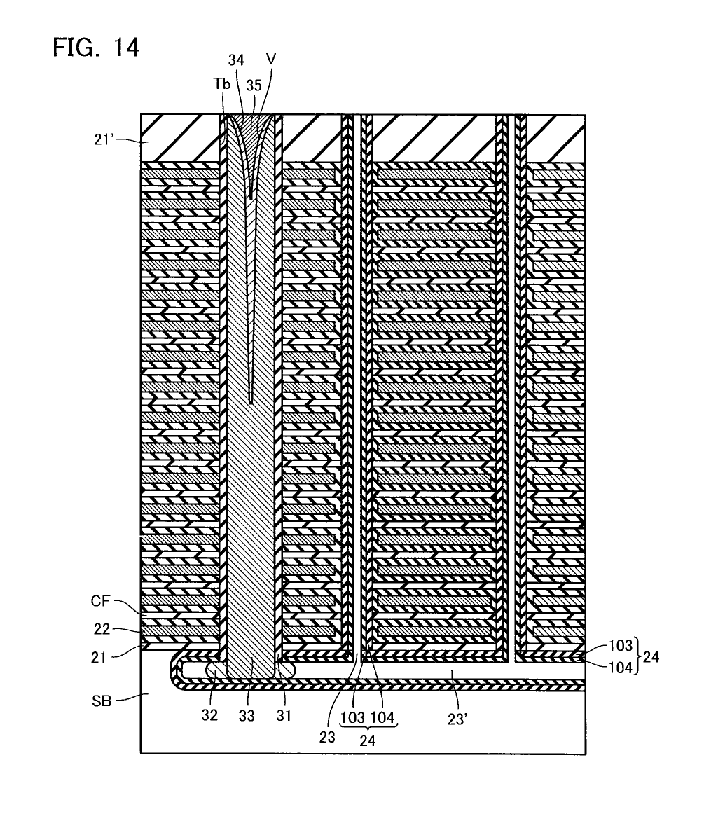

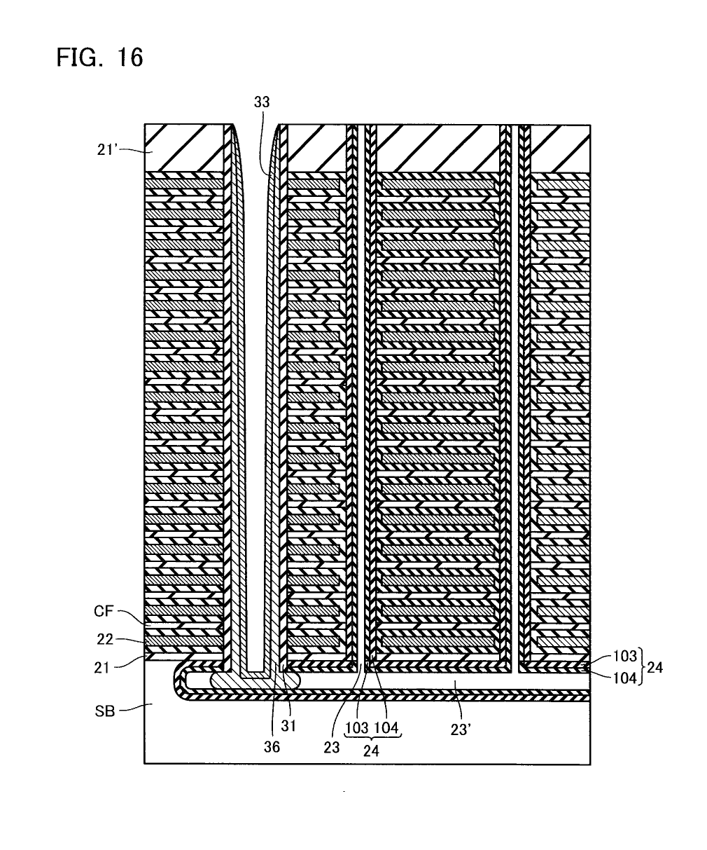

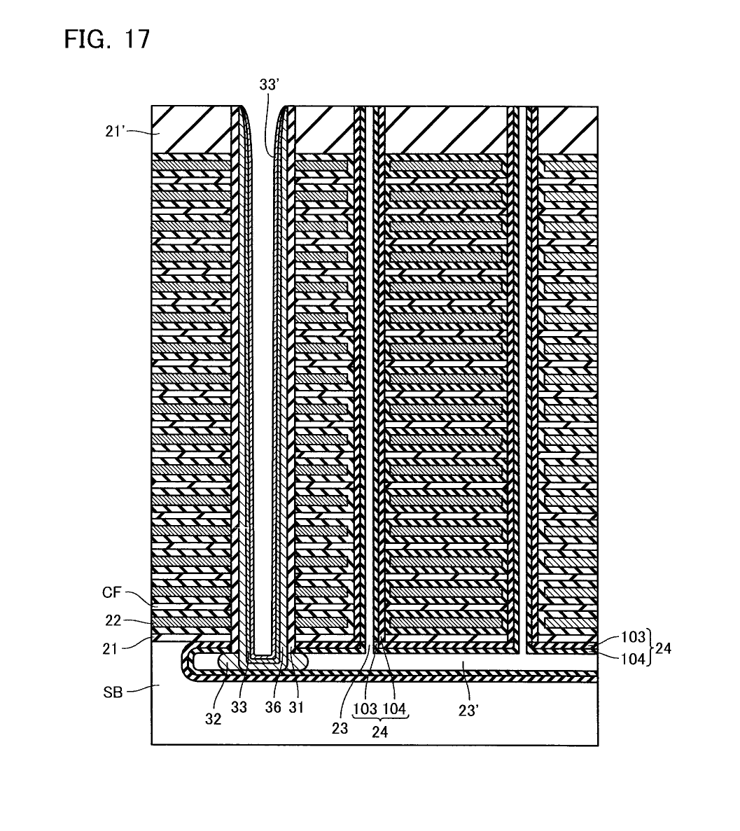

The following describes a nonvolatile semiconductor memory device 100 according to a second embodiment with reference to FIG. 14 to FIG. 18. In this second embodiment, the overall structure (in FIG. 1 to FIG. 5) is approximately similar to that of the first embodiment. Therefore, the overlapped description will not be further elaborated here. This second embodiment differs from a first embodiment in the structure of the contact LI as illustrated in FIG. 14.

The contact LI of this embodiment includes, similarly to the first embodiment, the semiconductor layer 32, the silicide film 33, the barrier metal film 34, and the metal film 35. However, the silicide film 33 of the second embodiment has a larger film thickness than that of the silicide film 33 of the first embodiment. On the lower side of the trench Tb, the silicide film 33 is formed to have a thickness to the extent of filling the trench Tb together with the interlayer insulating film 31. The silicide film 33 has a valley portion V only on the upper side of the silicide film 33. The barrier metal film 34 is formed along the inner wall of this valley portion V. Further, the metal film 35 faces the silicide film 33 via this barrier metal film 34. The metal film 35 is formed only in the valley portion V located in the upper portion of the trench Tb. This point is different from the first embodiment where the metal film 35 is formed to reach the lower side of the trench Tb.

In the case of the structure in this second embodiment, the film thickness of the silicide film 33 is increased. This allows decreasing the resistivity of the silicide film 33, thus reducing the resistance of the contact LI as a whole. This structure of the second embodiment can be obtained by using a metal that has a volume increased (expanded) after silicidation than the volume before silicidation and by repeatedly performing the silicidation process in the case where the silicide film 33 is formed.

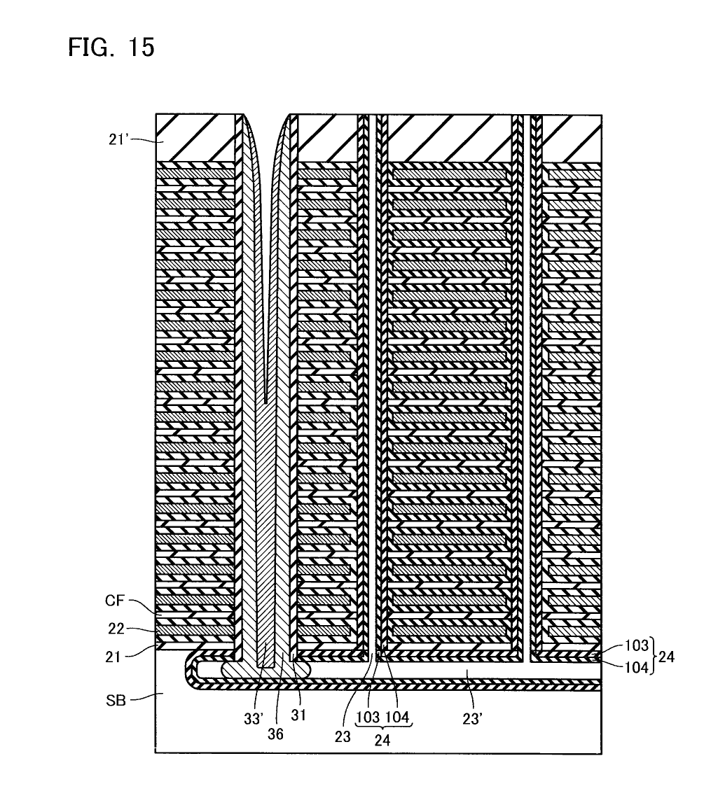

The following describes a method of manufacturing the contact LI in the nonvolatile semiconductor memory device of this second embodiment with reference to FIG. 15 to FIG. 18.

Firstly, similarly to the first embodiment (in FIG. 8 to FIG. 11), the trench Tb is formed, and the interlayer insulating film 31 is formed. Subsequently, as illustrated in FIG. 15, the polysilicon film 36 containing impurities such as boron (B) is deposited inside the trench Tb. Subsequently, the metal film 33′ is deposited on the inner wall of the polysilicon film 36. In the first embodiment, the film thickness of the polysilicon film 36 is set to the extent that the entire polysilicon film 36 is silicidized by one silicidation process. In contrast, the second embodiment is based on the premise that the silicidation process is repeated a plurality of times. Accordingly, the film thickness of the polysilicon film 36 is set to be thicker than that of the first embodiment. The metal film 33′ is deposited on the inner wall of the polysilicon film 36 by, for example, a sputtering method or similar method using nickel (Ni), cobalt (Co), or similar material as the material.

Subsequently, the silicidation process is performed to silicidize polysilicon in the polysilicon film 36. With the silicidation, polysilicon near the surface in the polysilicon film 36 is changed into the silicide film 33. In the polysilicon film 36, for example, polysilicon on the side close to the interlayer insulating film 31 is not silicidized and is left to be polysilicon.

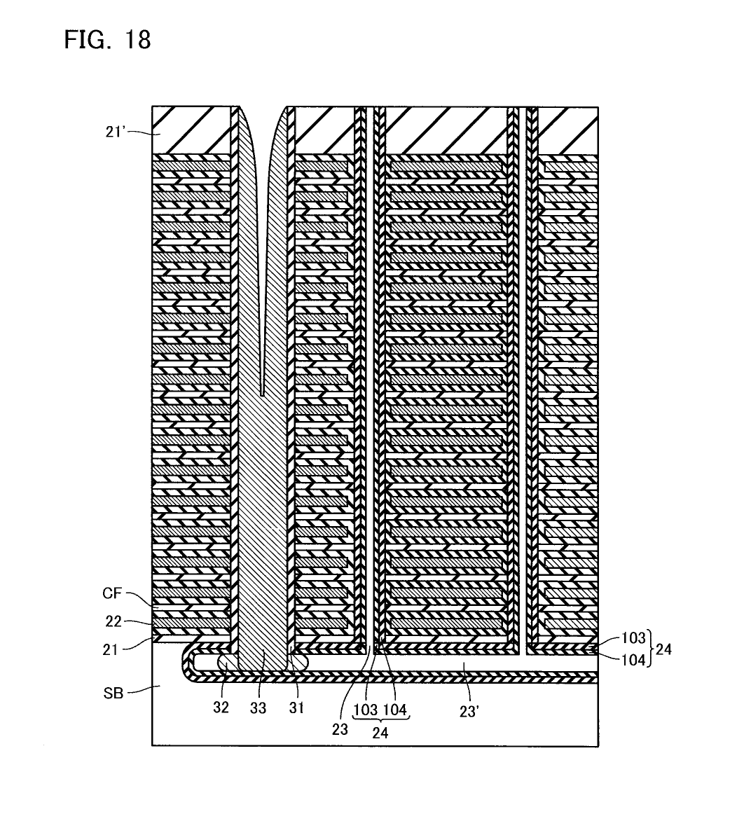

Subsequently, as illustrated in FIG. 17, the metal film 33′ is deposited again on the surface of the silicide film 33, and the silicidation process is performed again. This further enhances the silicidation of the polysilicon film 36. The deposition of the metal film 33′ and the silicidation process described above are repeated a plurality of times to silicidize the polysilicon film 36 as a whole, so as to form the silicide film 33 that has the large film thickness to the extent of filling the trench Tb at least in the bottom portion of the trench Tb (in FIG. 18). Lastly, the barrier metal film 34 and the metal film 35 are deposited in the remaining valley portion V. Thus, the structure of the contact LI illustrated in FIG. 14 is completed.

The second embodiment allows obtaining the same effects as those in the first embodiment. In addition, the second embodiment allows reducing the resistance of the contact LI compared with the first embodiment.

### Others

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device, comprising:
a semiconductor substrate;
a first semiconductor layer formed on a surface of the semiconductor substrate;
a memory cell array that includes a memory string formed to extend in a first direction vertical to the surface of the semiconductor substrate, the memory string being formed by coupling a plurality of memory cells in series;
a contact that extends in the first direction, the contact having one end coupled to the first semiconductor layer, wherein
the contact includes:
a second semiconductor layer formed in the first semiconductor layer, the second semiconductor layer having a higher impurity concentration than an impurity concentration of the first semiconductor layer;
a silicide film that has one end coupled to the second semiconductor layer, the silicide film extending in the first direction; and
a metal film formed on an inner wall of the silicide film.

2. The nonvolatile semiconductor memory device according to claim 1, further comprising
a barrier metal between the metal film and the silicide film.

3. The nonvolatile semiconductor memory device according to claim 1, wherein
the contact has one end coupled to the first semiconductor layer, and another end coupled to a source line.

4. The nonvolatile semiconductor memory device according to claim 1, wherein
the memory cell array includes:
a third semiconductor layer that functions as a body of the memory string, the third semiconductor layer extending along the first direction;
a memory layer formed on a side surface of the third semiconductor layer; and
a conducting layer that functions as a word line of the memory cell, the conducting layer being disposed to face the third semiconductor layer via the memory layer.

5. The nonvolatile semiconductor memory device according to claim 4, further comprising
a barrier metal between the metal film and the silicide film.

6. The nonvolatile semiconductor memory device according to claim 4, wherein
the contact has one end coupled to the first semiconductor layer, and another end coupled to a source line.

7. The nonvolatile semiconductor memory device according to claim 1, wherein
the memory cell array includes a laminated body where a conducting layer to be a word line of the memory cell and an interlayer insulating film are alternately laminated, and
the contact is formed via the interlayer insulating film on a trench passing through the laminated body.

8. The nonvolatile semiconductor memory device according to claim 7, further comprising
a barrier metal between the metal film and the silicide film.

9. The nonvolatile semiconductor memory device according to claim 7, wherein
the contact has one end coupled to the first semiconductor layer, and another end coupled to a source line.

10. The nonvolatile semiconductor memory device according to claim 7, wherein
the memory cell array includes:
a third semiconductor layer that functions as a body of the memory string, the third semiconductor layer extending along the first direction;
a memory layer formed on a side surface of the third semiconductor layer; and
a conducting layer that functions as a word line of the memory cell, the conducting layer being disposed to face the third semiconductor layer via the memory layer.

11. The nonvolatile semiconductor memory device according to claim 10, further comprising
a barrier metal between the metal film and the silicide film.

12. The nonvolatile semiconductor memory device according to claim 10, wherein
the contact has a one end coupled to the first semiconductor layer, and another end coupled to a source line.

13. A method of manufacturing a nonvolatile semiconductor memory device, wherein
the nonvolatile semiconductor memory device includes a memory string, the memory string being formed to extend in a first direction vertical to a surface of the semiconductor substrate, the memory string being formed by coupling a plurality of memory cells in series, wherein
the method comprises:
forming a laminated body by forming a first semiconductor layer on the semiconductor substrate and then alternately laminating a conducting layer to be a word line of the memory cell and an interlayer insulating film;
forming a trench that passes through the laminated body and reaches the first semiconductor layer;
forming an isolation film on a sidewall of the trench, the isolation film isolating the conducting layer;
forming a second semiconductor layer in the trench including a sidewall of the isolation film, the second semiconductor layer having a higher impurity concentration than an impurity concentration of the first semiconductor layer;
forming a silicide film by depositing a first metal film on an inner wall of the second semiconductor layer and then performing a heat treatment so as to silicidize a part of the silicon film; and
depositing a second metal film along a surface of the silicide film.

14. The method of manufacturing the nonvolatile semiconductor memory device according to claim 13, wherein
the depositing of the first metal film and the performing of the heat treatment are repeated a plurality of times.

15. The method of manufacturing the nonvolatile semiconductor memory device according to claim 13, wherein
the method forms the second metal film after a barrier film is formed on the surface of the silicide film.
